(19) United States
(12) Patent Application Publication
(10) Pub. No.: US 2018/0205010 A1
(43) Pub. Date: Jul. 19, 2018

(54) METHOD OF FABRICATING MEMORY DEVICE

(71) Applicant: Sang-hwan PARK, Hwaseong-si (KR)

(72) Inventor: Sang-hwan PARK, Hwaseong-si (KR)

(21) Appl. No.: 15/846,523

(22) Filed: Dec. 19, 2017

(30) Foreign Application Priority Data
Jan. 17, 2017 (KR) 10-2017-0008186

(51) Int. Cl. H01L 43/12; H01L 27/22; H01L 43/08

(52) U.S. Cl. CPC H01L 43/12; H01L 43/10; H01L 43/08; H01L 27/228

(57) ABSTRACT

A method of fabricating a memory device includes forming a magnetic tunnel junction (MTJ) layer on a substrate, the MTJ layer including a first magnetization layer, a second magnetization layer, and a tunnel barrier layer between the first magnetization layer and the second magnetization layer; subsequently forming a plurality of MTJ structures by patterning the MTJ layer; performing an annealing process on at least one of the MTJ layer prior to forming the plurality of MTJ structures and the MTJ structures after forming the plurality of MTJ structures; performing additional steps on the MTJ structures to form a variable resistance memory device including the plurality of MTJ structures; and after performing at least one of the additional steps, performing a magnetic field treatment process on the plurality of MTJ structures, the magnetic field treatment process being performed without simultaneously performing any annealing process.

### CROSS-REFERENCE TO RELATED APPLICATION

This application claims the benefit of priority to Korean Patent Application No. 10-2017-0008186, filed on Jan. 17, 2017, in the Korean Intellectual Property Office, the disclosure of which is incorporated herein in its entirety by reference.

### BACKGROUND

The present disclosure relates to a method of fabricating a memory device, and more particularly, to a method of fabricating a variable resistance memory device including a magnetic tunnel junction (MTJ) structure including a transition metal having magnetism.

As the speed of electronic products increases and the power consumption of electronic products decreases, demand for fast read/write operations and low operating voltages of semiconductor devices in such electronic products has increased. In response to this demand, a vast amount of research has been conducted on variable resistance electronic devices using magneto-resistive characteristics of an MTJ. In particular, since the variable resistance memory devices are non-volatile, the variable resistance memory devices have emerged as a next-generation memory device. Recently, Spin-transfer Torque Magnetic Random-Access Memory (STT-MRAM), which is advantageous in improving recording density, has been actively studied.

### SUMMARY

The example embodiments provide methods of fabricating memory devices with improved productivity and fabrication efficiency.

The example embodiments are not limited to the above objectives, but other objectives not described herein may be clearly understood by those skilled in the art from the description below.

According to some example embodiments, a method of fabricating a memory device includes forming a magnetic tunnel junction (MTJ) layer on a substrate, the MTJ layer including a first magnetization layer, a second magnetization layer, and a tunnel barrier layer between the first magnetization layer and the second magnetization layer; performing a first annealing process on the MTJ layer; subsequently forming a plurality of MTJ structures by patterning the MTJ layer; subsequently performing a second annealing process on the plurality of MTJ structures at a temperature lower than that of the first annealing process; subsequently performing additional steps to form a variable resistance memory device including the plurality of MTJ structures; and after performing at least one of the additional steps, performing a magnetic field treatment process on the plurality of MTJ structures.

According to some example embodiments, a method of fabricating a memory device may include forming a magnetic tunnel junction (MTJ) layer on a substrate, the MTJ layer including a free layer, a fixed layer, and a tunnel barrier layer between the free layer and the fixed layer; a first device performing a first annealing process on the MTJ layer; after performing the first annealing process, forming a plurality of MTJ structures by patterning the MTJ layer; after forming the plurality of MTJ structures, performing a second annealing process on the plurality of MTJ structures at a temperature lower than that of the first annealing process; after the second annealing process, performing additional steps to form a variable resistance memory device including the plurality of MTJ structures; and a second device different from the first device performing a magnetic field treatment process on the plurality of MTJ structures, after one or more of the additional steps, to align magnetization directions of the free layer.

According to some example embodiments, a method of fabricating a memory device includes forming a magnetic tunnel junction (MTJ) layer on a substrate, the MTJ layer including a first magnetization layer, a second magnetization layer, and a tunnel barrier layer between the first magnetization layer and the second magnetization layer; subsequently forming a plurality of MTJ structures by patterning the MTJ layer; performing an annealing process on at least one of the MTJ layer prior to forming the plurality of MTJ structures and the MTJ structures after forming the plurality of MTJ structures; performing additional steps on the MTJ structures to form a variable resistance memory device including the plurality of MTJ structures; and after performing at least one of the additional steps, performing a magnetic field treatment process on the plurality of MTJ structures, the magnetic field treatment process being performed without simultaneously performing any annealing process.

### BRIEF DESCRIPTION OF THE DRAWINGS

Example embodiments of the inventive concept will be more clearly understood from the following detailed description taken in conjunction with the accompanying drawings in which:

FIG. 1 is a view of a schematic configuration of a variable resistance memory device fabricated by a method of fabricating a memory device according to an example embodiment;

FIG. 2 is a cross-sectional view of a magnetic memory element of a variable resistance memory device fabricated by a method of fabricating a memory device according to an example embodiment;

FIG. 3 is a flowchart of a method of fabricating a memory device according to an example embodiment;

FIG. 4 is a circuit diagram of a cell array of a variable resistance memory device fabricated by a method of fabricating a memory device according to an example embodiment;

FIGS. 5A through 5F are cross-sectional views of a process sequence of a method of fabricating a memory device according to an example embodiment;

FIGS. 6A and 6B are views for comparing magnetization directions of a variable resistance memory device fabricated by a method of fabricating a memory device according to an example embodiment;

FIG. 7 is a cross-sectional view of an annealing device for a method of fabricating a memory device according to an example embodiment;

FIG. 8 is a cross-sectional view of a magnetic field treatment device for a method of fabricating a memory device according to an example embodiment; and

FIG. 9 is a block diagram of an electronic system including a variable resistance memory device fabricated by a method of fabricating a memory device according to an example embodiment.

### DETAILED DESCRIPTION

The present disclosure now will be described more fully hereinafter with reference to the accompanying drawings, in which various exemplary embodiments are shown. The invention may, however, be embodied in many different forms and should not be construed as limited to the exemplary embodiments set forth herein. These example exemplary embodiments are just that—examples—and many embodiments and variations are possible that do not require the details provided herein. It should also be emphasized that the disclosure provides details of alternative examples, but such listing of alternatives is not exhaustive. Furthermore, any consistency of detail between various exemplary embodiments should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

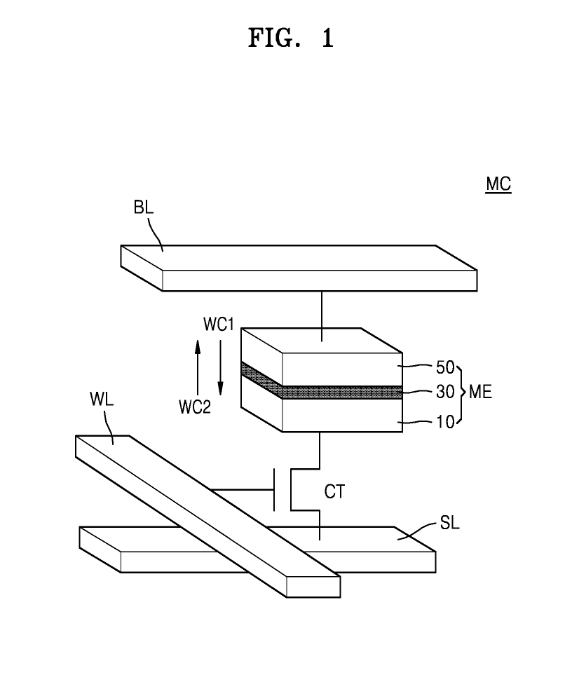

FIG. 1 is a view of a schematic configuration of a variable resistance memory device fabricated by a method of fabricating a memory device according to an example embodiment.

FIG. 1 shows a unit memory cell MC including Spin-Transfer Torque Magnetic Random-Access Memory (STT-MRAM).

The unit memory cell MC may include a magnetic memory element ME, which includes a magnetic tunnel junction (MTJ), and a cell transistor CT. A gate of the cell transistor CT may be connected to a word line WL. Also, one of the electrodes of the cell transistor CT may be connected to a bit line BL through the magnetic memory element ME, and the other electrode may be connected to a source line SL.

The magnetic memory element ME may include a fixed layer 10 and a free layer 50, and a tunnel barrier layer 30 interposed therebetween. The fixed layer 10 has an easy axis of magnetization in a direction perpendicular to an extending (e.g., lengthwise) direction of the fixed layer 10 and has a fixed magnetization direction. In contrast, the free layer 50 has an easy axis of magnetization in a direction perpendicular to an extending direction of the free layer 50, and a magnetization direction thereof is variable depending on conditions.

A resistance value of the magnetic memory element ME depends on a magnetization direction of the free layer 50. When a magnetization direction of the free layer 50 and a magnetization direction of the fixed layer 10 are parallel, the magnetic memory element ME has a relatively low resistance value and may store data ‘0’. On the other hand, when a magnetization direction of the free layer 50 and a magnetization direction of the fixed layer 10 are antiparallel, the magnetic memory element ME has a relatively high resistance value and may store data ‘1’.

An arrangement of the fixed layer 10 and the free layer 50 is not limited to that shown in FIG. 1, and positions of the fixed layer 10 and the free layer 50 may be switched.

In some example embodiments, the unit memory cell MC applies a logic-high voltage to the word line WL and turns on the cell transistor CT for a write operation of STT-MRAM, and applies write currents WC1 and WC2 between the bit line BL and the source line SL. A magnetization direction of the free layer 50 may be determined according to directions of the write currents WC1 and WC2. The magnetization direction of the free layer 50 in the magnetic memory element ME may be varied by STT. The magnetic memory element ME may perform a memory function by using an STT phenomenon in which a magnetization direction of a magnetic substance is varied by an input current.

In some example embodiments, the unit memory cell MC applies a logic-high voltage to the word line WL and turns on the cell transistor CT for a read operation of STT-MRAM, and may read data stored in the magnetic memory element ME by applying a read current in a direction from the bit line BL to the source line SL. Since an intensity of the read current is relatively less than intensities of the write currents WC1 and WC2, a magnetization direction of the free layer 50 is not changed by the read current.

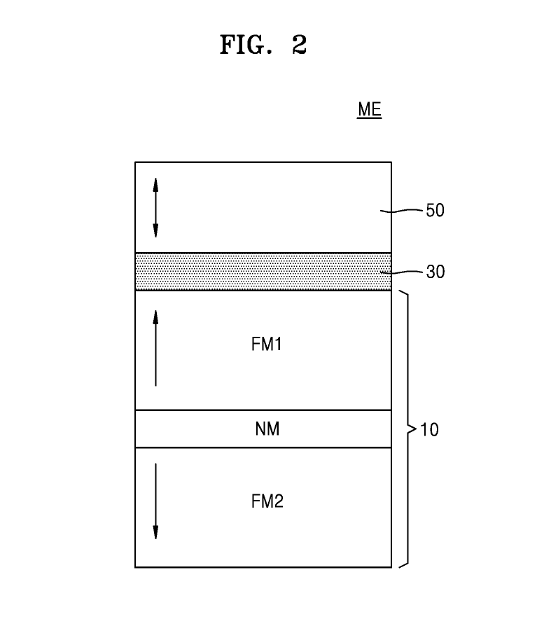

FIG. 2 is a cross-sectional view of a magnetic memory element ME of a variable resistance memory device fabricated by a method of fabricating a memory device according to an example embodiment.

Referring to FIG. 2, the magnetic memory element ME may include the free layer 50 including a ferromagnetic layer structure, the fixed layer 10 including a synthetic antiferromagnetic layer structure, and the tunnel barrier layer 30 interposed therebetween.

The fixed layer 10 may include two ferromagnetic layers FM1 and FM2 separated from each other by a non-magnetic layer NM. Antiferromagnetic binding characteristics appear in the synthetic antiferromagnetic layer structure due to a Ruderman-Kittel-Kasuya-Yosida (RKKY) interaction from a non-magnetic layer NM interposed between the two ferromagnetic layers FM1 and FM2. Respective magnetization directions of the ferromagnetic layers FM1 and FM2 are aligned in opposite directions with respect to each other by the antiferromagnetic binding between the two ferromagnetic layers FM1 and FM2 so that the total amount of magnetization of the synthetic antiferromagnetic layer structure may be minimized. The magnetization directions of the two ferromagnetic layers FM1 and FM2 included in the fixed layer 10 do not change.

The tunnel barrier layer 30 may include a non-magnetic material.

A magnetization direction of the free layer 50 may be varied by an applied magnetic field. A resistance value is determined according to whether a magnetization direction of the free layer 50 and a magnetization direction of the fixed layer 10 are parallel or antiparallel. When a magnetic field applied to the free layer 50 from outside gradually increases to a switching field which is a threshold of a magnetization reversal, the resistance value may be instantaneously changed by a magnetization reversal phenomenon.

In order to use the magnetic memory element ME having a resistance value determined by magnetization directions of the free layer 50 and the fixed layer 10 as a variable resistance memory device, there is a need to align the magnetization directions.

Generally, in order to align magnetization directions in the magnetic memory element ME, a magnetic field annealing process is mainly used in which a magnetic field of several teslas T is applied while maintaining a temperature of 300° C. or more in a very high vacuum chamber for the magnetic memory element ME. The magnetic field annealing process has been performed as an essential process on a horizontal magnetization memory device, and is also performed on a vertical magnetization memory device.

In order to align magnetization directions of the magnetic memory element ME, the magnetic field annealing process should be capable of simultaneously applying a uniform magnetic field of several T to several tens of substrates in an environment of 300° C. or more. In order to satisfy such a condition, a magnetic field annealing device mainly using a superconducting magnet is used. However, due to an area of the superconducting magnet, the magnetic field annealing device using the superconducting magnet may require a footprint four times larger than that of another annealing device that does not include a superconducting magnet.

In order to improve productivity and fabrication efficiency of a variable resistance memory device by reducing such a footprint and performing an annealing process and magnetic field treatment in different fabricating devices, a method of fabricating a memory device according to example embodiments provides a fabricating process that can replace a magnetic field annealing process in the magnetic memory element ME.

Also, a method of fabricating a memory device capable of optimizing characteristics of a variable resistance memory device may be provided by variables of a first annealing process before patterning the magnetic memory element ME and a second annealing process after patterning the magnetic memory element ME, for example, an influence of temperature and time on characteristics of the magnetic memory element ME.

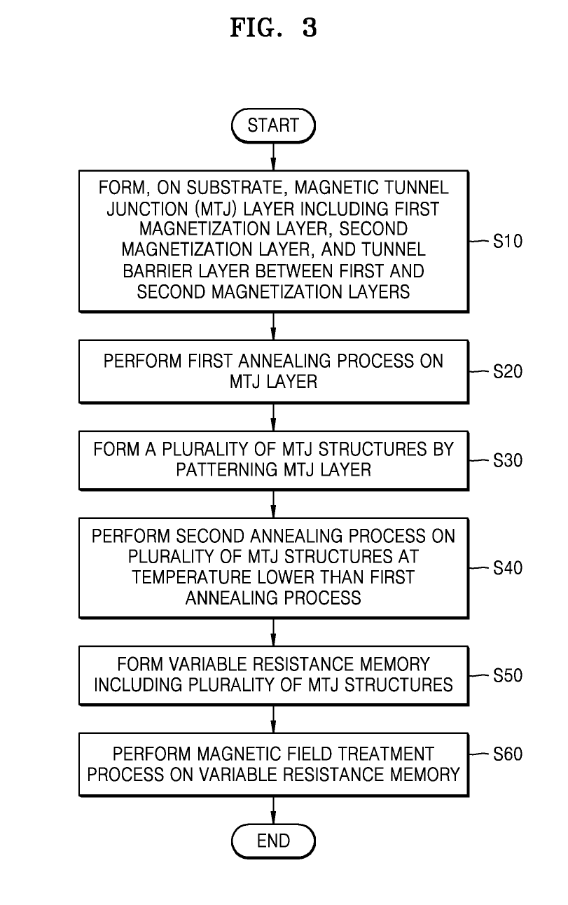

FIG. 3 is a flowchart of a method of fabricating a memory device according to an example embodiment of the inventive concept.

FIG. 3 sequentially shows operation S10 of forming an MTJ layer on a substrate, the MTJ layer including first and second magnetization layers, and a tunnel barrier layer between the first and second magnetization layers, subsequent operation S20 of performing a first annealing process on the MTJ layer, subsequent operation S30 of forming a plurality of MTJ structures by patterning the MTJ layer (e.g., patterning the annealed MTJ layer after the first annealing process), subsequent operation S40 of performing a second annealing process on the plurality of MTJ structures (e.g., on the patterned MTJ layer) at a temperature lower than the temperature used for annealing in the first annealing process, operation S50 of forming a variable resistance memory including a plurality of MTJ structures, and operation S60 of performing magnetic field treatment on the variable resistance memory.

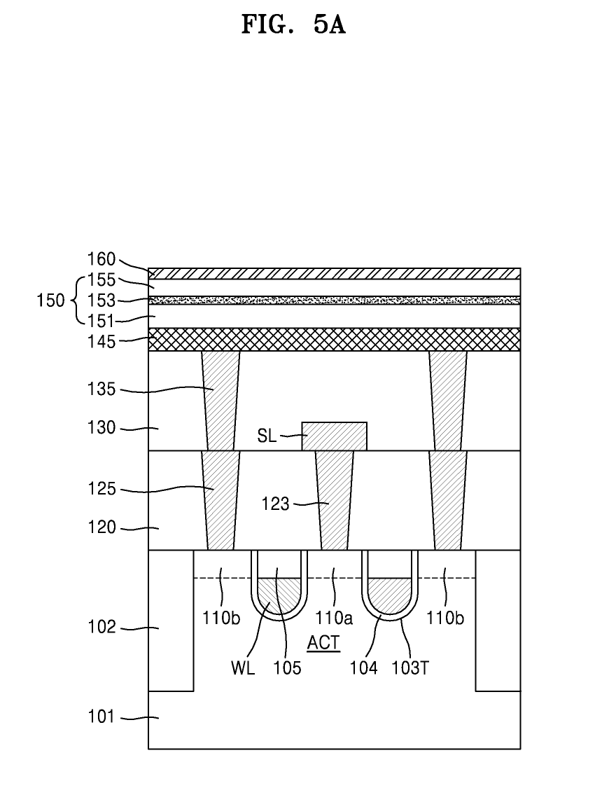

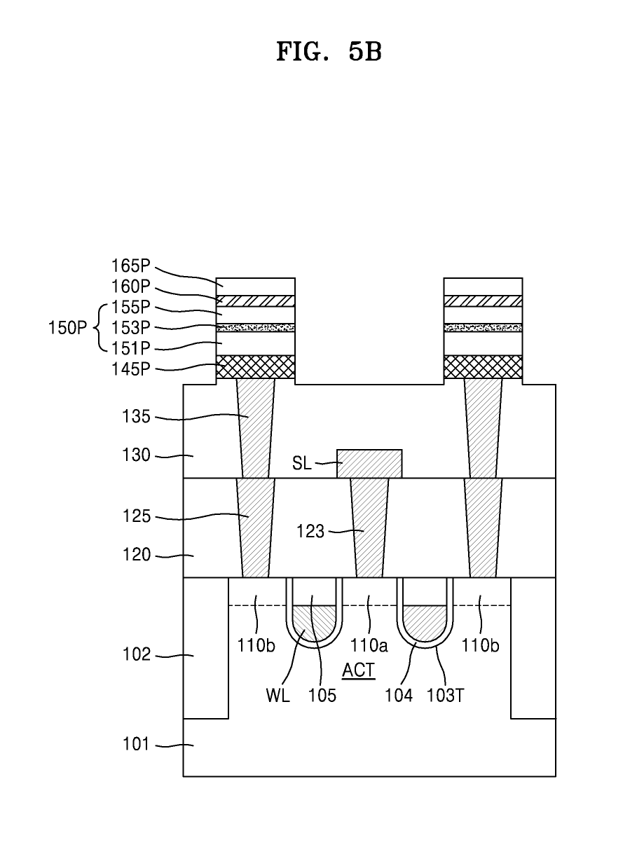

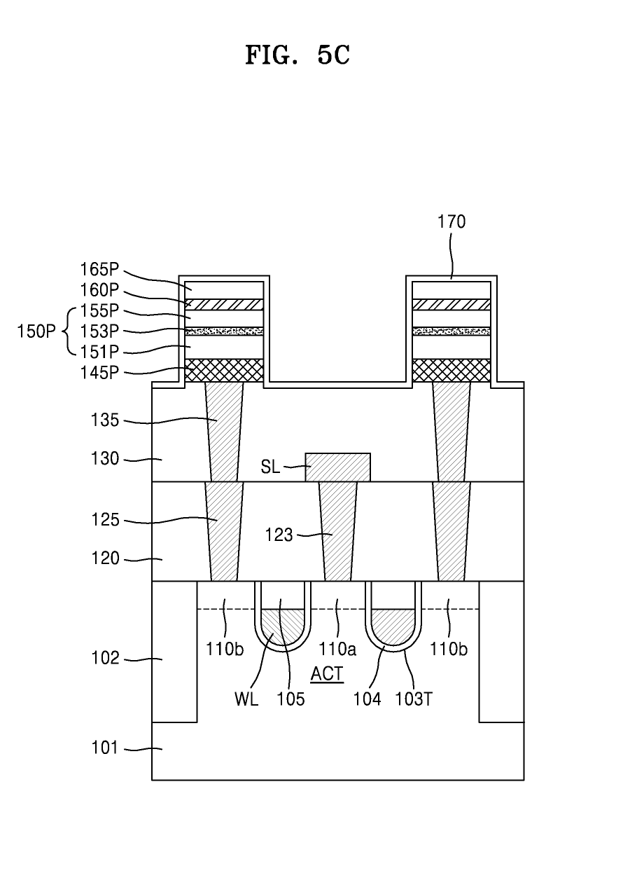

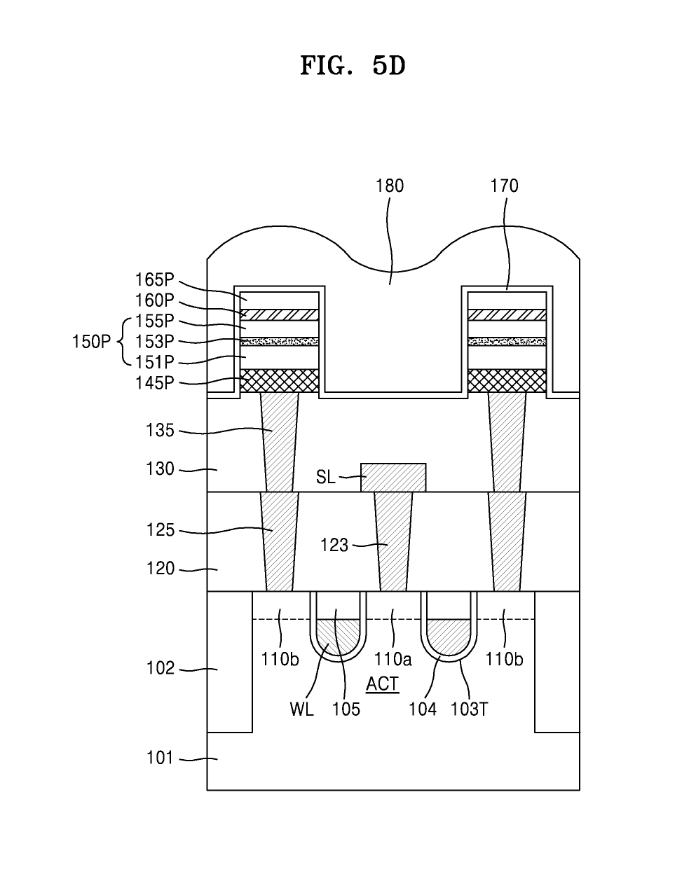

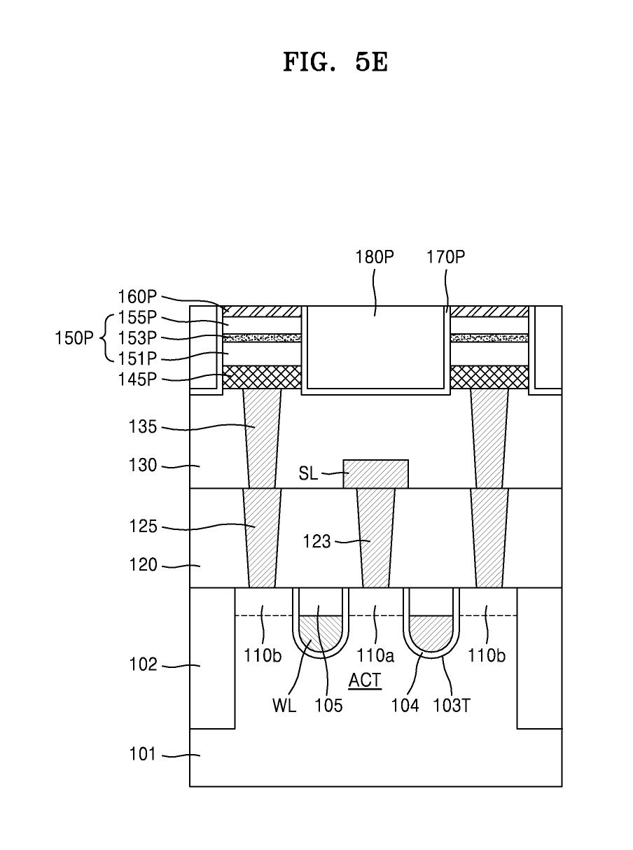

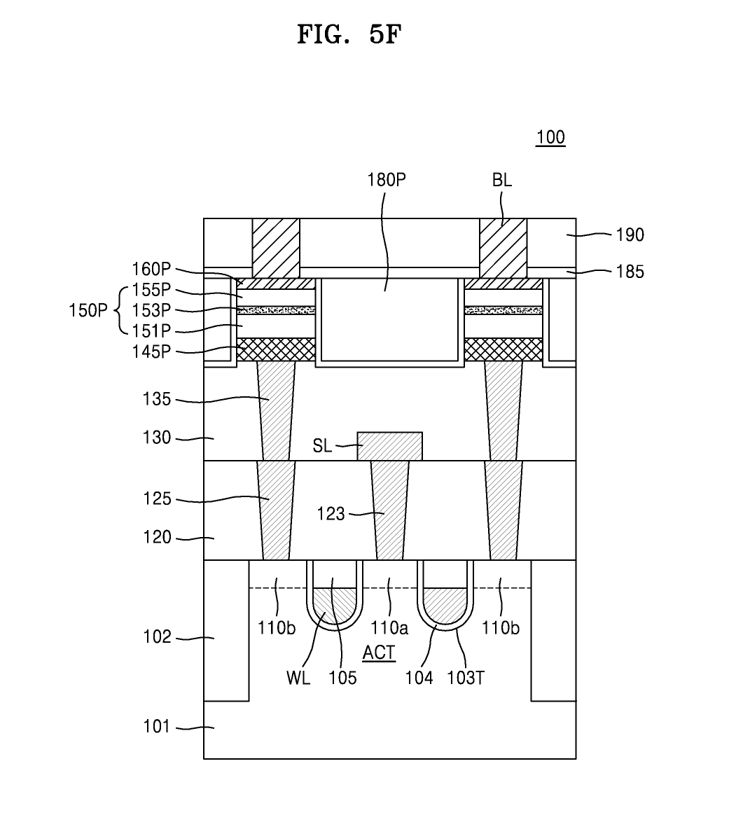

A specific method of fabricating a memory device in operations S10 through S60 will be described in detail later below with reference to FIGS. 5A through 5F.

Here, characteristics of a memory device fabricated through operations S10 through S60 (hereinafter referred to as an experimental example) are compared with characteristics of a memory device (hereinafter referred to as a comparative example) fabricated by performing a general magnetic field annealing process.

In the experimental example, the first annealing process in operation S20 is performed at a temperature of 350° C. for one hour, and the second annealing process in operation S40 is later performed at a temperature of 300° C. for one hour. Then, in operation S60, the magnetic field treatment process is performed for one hour at a magnetic flux density of 5 T (e.g., at room temperature).

In the comparative example, a magnetic field annealing process is performed on an MTJ layer at a temperature of 350° Cand a magnetic flux density of 5 T for one hour. Later, the magnetic field annealing process is performed on a plurality of MTJ structures at a temperature of 300° C. and a magnetic flux density of 5 T for one hour. Therefore, in this example, the annealing and the magnetic field treatment processes are essentially combined to be performed in a single process each time, which can be performed in a single fabricating machine or device. On the contrary, in the experimental example, the annealing process is performed separately from the magnetic field treatment process, for example in different respective fabricating machines or devices and at different times. In this manner, one or more annealing processes may be performed without simultaneously performing a magnetic field treatment process, and then later a magnetic field treatment process may be performed without simultaneously performing an annealing process.

Characteristics of the experimental example and the comparative example fabricated by the above fabricating method are shown in Table 1 below.

TABLE 1

| | TMR | Hc | Vsw |
|---|---|---|---|
| experimental example | 163% | 1,849 Oe | −0.31 V |
| comparative example | 168% | 1,832 Oe | −0.31 V |

In Table 1, TMR is a tunneling magnetoresistance ratio, He is a critical magnetic field, and Vsw is a switching voltage. Ersted (Oe) is used as a unit of Hc. All of the above characteristics are typical factors for evaluating magnetization characteristics of the magnetic memory element ME. The experimental example and the comparative example show a difference of about 5 (about 3% difference) in a TMR characteristic and about 17 (about 1% difference) in an He characteristic, and have an identical Vsw characteristic (0%). It can be seen that the experimental example and the comparative example exhibit substantially the same magnetization characteristics within an error range.

As a result, a method of fabricating a memory device according to the example embodiments may improve productivity and fabrication efficiency of a memory device while magnetization characteristics of a variable resistance memory device is substantially the same as that of a memory device fabricated by a method of fabricating a memory device through a general magnetic field annealing process.

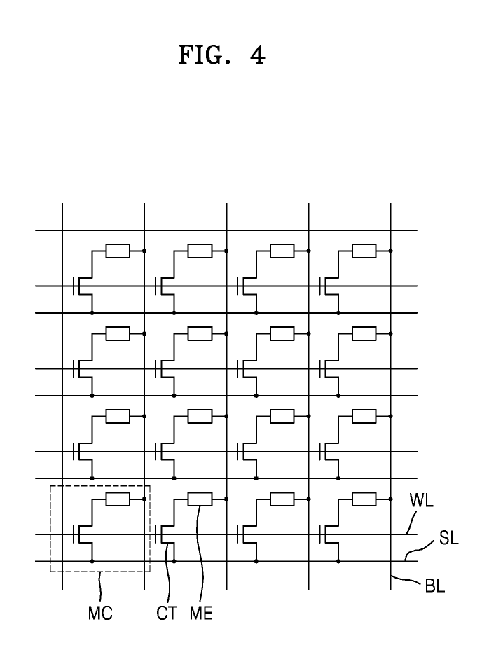

FIG. 4 is a circuit diagram of a cell array of a variable resistance memory device fabricated by a method of fabricating a memory device according to an example embodiment of the inventive concept.

Referring to FIG. 4, a plurality of unit memory cells MC may be arranged two-dimensionally or three-dimensionally.

The unit memory cells MC may be connected between the word lines WL and the bit lines BL which intersect each other. Each of the unit memory cells MC may include the magnetic memory element ME including an MTJ and the cell transistor CT. The cell transistor CT and the magnetic memory element ME may be electrically connected in series with each other. The magnetic memory element ME may be connected to one end of the cell transistor CT and the source line SL may be connected to another end of the cell transistor CT.

The word line WL and the bit line BL may be arranged such that they form a certain angle, for example, perpendicular to each other. Furthermore, the word line WL and the bit line BL may be arranged such that they form another certain angle, for example, in parallel with each other.

FIGS. 5A through 5F are cross-sectional views of a process sequence of a method of fabricating a memory device according to an example embodiment.

Referring to FIG. 5A, a first annealing process may be performed after forming an active area ACT and the word line WL in a substrate 101, and after forming an MTJ layer 150 over the substrate 101.

The substrate 101 may include silicon (Si), for example, crystalline Si, polycrystalline Si, or amorphous Si. Alternatively, the substrate 101 may include at least one material selected from a semiconductor element such as germanium (Ge), silicon germanium (SiGe), silicon carbide (SiC), gallium arsenide (GaAs), indium arsenide (InAs), and indium phosphide (InP). Alternatively, the substrate 101 may include a silicon on insulator (SOI) structure. Alternatively, the substrate 101 may include a conductive area, for example, wells doped with impurities or a structure doped with impurities. The substrate 101 may be in the form of a wafer.

First, the active area ACT may be defined by forming an element isolation layer 102 in the substrate 101. The element isolation layer 102 may include an insulating material. The element isolation layer 102 may be formed, for example, by a shallow trench isolation (STI) process. The element isolation layer 102 may be, for example, a silicon oxide, a silicon nitride, a silicon oxynitride, or a combination thereof. The active area ACT may include first and second impurity areas 110a and 110b formed by ion-implanting impurities at a predetermined depth in an upper portion thereof. The first and second impurity areas 110a and 110b may be shallower than a depth to a lower surface of the word line WL. The first and second impurity areas 110a and 110b may serve as source/drain areas of a transistor formed by, for example, the word line WL.

Next, the word line WL may be formed in the active area ACT. A plurality of trenches 103T may be formed in the substrate 101 and then a gate insulating layer 104 and the word line WL including a conductive material may be sequentially formed in each of the trenches 103T. A gate capping layer 105 filling the remaining space in each of the trenches 103T may be formed on the word line WL. The word line WL is formed in each of the trenches 103T and an upper surface of the word line WL may be lower than that of the active area ACT.

A Buried Channel Array Transistor (BCAT) including a buried word line WL has been described as an example. However, in some example embodiments, the BCAT may be transformed into, but is not limited to, a planar transistor, a Recess Channel Array Transistor (RCAT), a Sphere-shaped Recess Channel Array Transistor (SRCAT), or the like.

Next, a first interlayer insulating layer 120 and first and second contact plugs 123 and 125 may be formed over the substrate 101 in which the active area ACT and the word line WL are formed.

The first interlayer insulating layer 120 may include silicon oxide. Alternatively, the first interlayer insulating layer 120 may include at least one material selected from boro-phospho-silicate glass (BPSG), tonen silazene (TOSZ), undoped silicate glass (USG), spin-on glass (SOG), flowable oxide (FOX), tetraethyl orthosilicate (TEOS), and high-density plasma chemical vapor deposition (HDP-CVD) oxide.

Contact holes penetrating through the first interlayer insulating layer 120 may be formed by removing a part of the first interlayer insulating layer 120 by using an exposure process and an etching process. Thereafter, a conductive material may be formed to fill the contact holes on the first interlayer insulating layer 120, and first and second contact plugs 123 and 125 connected to the first and second impurity regions 110a and 110b may be formed by removing the conductive material until an upper surface of the first interlayer insulating layer 120 is exposed through a planarization process such as a chemical mechanical polishing (CMP) process or an etch-back process. The first and second contact plugs 123 and 125 may include, for example, at least one material selected from doped silicon, tungsten (W), aluminum (Al), titanium (Ti), tantalum (Ta), titanium nitride (TiN), tantalum nitride (TaN), tungsten nitride (WN), and metal silicide.

Next, the source line SL may be formed by forming a conductive material connected to the first contact plug 123 on the first interlayer insulating layer 120 and patterning the conductive material. The conductive material may include at least one of doped polysilicon, a metal silicide, a metal, or a metal nitride.

Next, a second interlayer insulating layer 130 covering the source line SL may be formed on the first interlayer insulating layer 120. The second interlayer insulating layer 130 may include the same material as or similar material to the first interlayer insulating layer 120. A part of the second interlayer insulating layer 130 may be removed to form contact holes such that at least a part of an upper surface of the second contact plug 125 is exposed. A third contact plug 135 connected to the second contact plug 125 may be formed by filling a conductive material in the contact holes and performing a planarization process. The third contact plug 135 may include the same material as or similar material to the second contact plug 125.

Next, a lower electrode 145 covering a plurality of third contact plugs 135 and the second interlayer insulating layer 130 may be formed. The lower electrode 145 may include a conductive material such as Ti, Ta, ruthenium (Ru), TiN, TaN, or W. In some example embodiments, the lower electrode 145 may have a double-layered structure such as Ru/Ti, Ru/Ta, Ru/TiN, Ru/TaN, or TiN/W. The lower electrode 145 may be formed, for example, by an atomic layer deposition process or a chemical vapor deposition (CVD) process.

Next, a first magnetization layer 151, a tunnel barrier layer 153, a second magnetization layer 155, and a capping electrode layer 160 may be sequentially formed on the lower electrode 145 in this stated order. The first magnetization layer 151, the tunnel barrier layer 153, the second magnetization layer 155, and the capping electrode layer 160 may be formed, for example by an atomic layer deposition process or a CVD process. The first magnetization layer 151, the tunnel barrier layer 153, and the second magnetization layer 155 may constitute the MTJ layer 150.

The first magnetization layer 151 may include a magnetic material including a transition metal. A magnetization direction of the first magnetization layer 151 may be vertical. In some example embodiments, the first magnetization layer 151 may be a fixed layer having a magnetization direction which is fixed vertically. The first magnetization layer 151 may include at least one material selected from palladium (Pd), cobalt (Co), platinum (Pt), iron (Fe), Ru, Ta, nickel (Ni), boron (B), manganese (Mn), antimony (Sb), aluminum (Al), chromium (Cr), molybdenum (Mo), silicon (Si), copper (Cu), iridium (Ir), and alloys thereof. A material included in the first magnetization layer 151 may be, for example, cobalt-iron (CoFe), nickel-iron (NiFe), or cobalt-iron-boron (CoFeB). The first magnetization layer 151 may be formed by stacking one or at least two of the materials.

The first magnetization layer 151 is desirably formed as a film having a suitable alignment and a reduced crystal defect, and thus, may be formed to be thicker than other layers in the MTJ layer 150. Furthermore, the first magnetization layer 151 may have a synthetic antiferromagnetic layer structure. The synthetic antiferromagnetic layer structure may be a multilayered structure in which a plurality of magnetization layers and at least one intermediate layer are sequentially stacked. In some example embodiments, the synthetic antiferromagnetic layer structure may be a multilayered structure in which a first ferromagnetic layer, a non-magnetic layer, and a second ferromagnetic layer are sequentially stacked, as illustratively shown in FIG. 2.

For example, the first and second ferromagnetic layers may include at least one material selected from CoFeB, CoFe, NiFe, cobalt-iron-platinum (CoFePt), cobalt-iron-palladium (CoFePd), cobalt-iron-chromium (CoFeCr), cobalt-iron-terbium (CoFeTb), cobalt-iron-gadolinium (CoFeGd), cobalt-iron-nickel (CoFeNi), cobalt-iron (CoFe), nickel-iron (NiFe), and the like.

The nonmagnetic layer may include a nonmagnetic material and may include at least one material selected from Ru, Ir, rhodium (Rh), Cr, Cu, and the like. The first ferromagnetic layer may have a magnetization direction which is fixed. A magnetization direction of the second ferromagnetic layer may be fixed in a direction opposite to that of the first ferromagnetic layer.

The tunnel barrier layer 153 may be formed on the first magnetization layer 151. The tunnel barrier layer 153 may include an insulating metal oxide. For example, the tunnel barrier layer 153 may include magnesium oxide (MgO) or aluminum oxide (AlOx). The tunnel barrier layer 153 may be formed such that a quantum tunneling phenomenon is generated between the first magnetization layer 151 and a second magnetization layer 155. The tunnel barrier layer 153 may have a relatively small thickness of about 1 Å to about 100 Å but is not limited thereto.

The second magnetization layer 155 may be formed on the tunnel barrier layer 153. The second magnetization layer 155 may include a magnetic material including a transition metal. The second magnetization layer 155 may be a free layer capable of changing its magnetization direction vertically. The second magnetization layer 155 may include at least one material selected from Pd, Co, Pt, Fe, Ru, Ta, Ni, B, Mn, Sb, Al, Cr, Mo, Si, Cu, Ir, and alloys thereof (alloys which include at least one magnetic metal among these metals). A material included in the second magnetization layer 155 may be, for example, CoFe, NiFe, or CoFeB. The second magnetization layer 155 may be formed by stacking one or at least two of the materials.

In some example embodiments, a thickness of the second magnetization layer 155 formed as a free layer may be less than that of the first magnetization layer 151. A sum of thicknesses of the first magnetization layer 151, the tunnel barrier layer 153, and the second magnetization layer 155 may be about 150 Å to about 400 Å but is not limited thereto.

Here, the first magnetization layer 151 is a fixed layer and the second magnetization layer 155 is a free layer but the exemplary embodiments are not limited thereto. Any one of the first magnetization layer 151 and the second magnetization layer 1155 may be a fixed layer and the other may be a free layer. In some example embodiments, the first magnetization layer 151 may be a free layer and the second magnetization layer 155 may be a fixed layer.

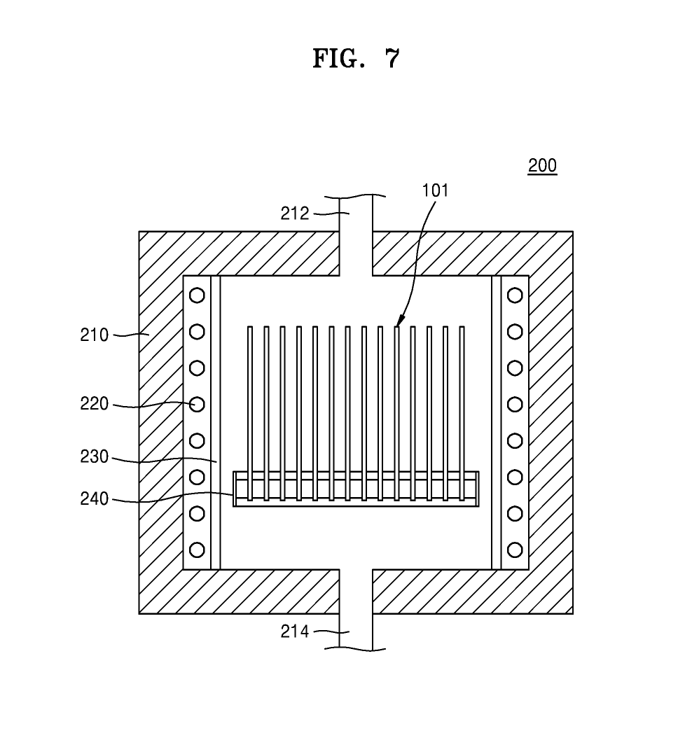

A first annealing process is performed on the MTJ layer 150. The first annealing process may be performed in a state in which a magnetic field is not formed. In some embodiments, the first annealing process may be performed by a batch type annealing device 200 of FIG. 7.

In more detail, the first annealing process may be performed for a first amount of time (e.g., one hour) under a first pressure (e.g., a pressure in a range of 0.1 mTorr or less) and a first temperature (e.g., a temperature in the range of 300° C. to 400° C.). The first annealing process may be performed in a gas atmosphere including at least one of hydrogen, oxygen, and nitrogen. In addition, an inert gas may be injected together into the gas atmosphere to control pressure during the first annealing process.

In some example embodiments, the first annealing process may be performed first in a gas atmosphere including hydrogen, and then performed in a gas atmosphere including oxygen and nitrogen. The first annealing process may be performed in a state in which a magnetic field is not formed in a first device. A magnetization direction of the MTJ layer 150 formed over the substrate 101 may be made to coincide with a desired direction even in the state in which a magnetic field is not formed. As described above, in order to align a magnetization direction in a desired direction, magnetic field treatment may not be performed simultaneously with an annealing process.

Referring to FIG. 5B, a mask pattern 165P is formed on the capping electrode layer 160 (FIG. 5A) so as to correspond to a position of the third contact plug 135. The capping electrode layer 160 (of FIG. 5A), the second magnetization layer 155 (of FIG. 5A), the tunnel barrier layer 153 (of FIG. 5A), the first magnetization layer 151 (of FIG. 5A), and the lower electrode layer 145 (of FIG. 5A) are sequentially patterned using the mask pattern 165P as an etching mask. Thus, a plurality of MTJ structures (a single MTJ structure 150P is labeled) including a second magnetization pattern 155P, a tunnel barrier pattern 153P, and a first magnetization pattern 151P may be formed. In the description below, a single MTJ structure 150P may be described as a representative of the plurality of MTJ structures 150P.

The mask pattern 165P may include silicon oxide, silicon nitride, silicon oxynitride, or the like. The patterning may be performed, for example, by dry etching. In more detail, the patterning may be performed by an ion-beam etching process or a reactive ion-etching process. An upper surface of the second interlayer insulating layer 130, which is exposed between MTJ structures 150P of the MTJ structure pattern, may be recessed during the etching process. The MTJ structure 150P is shown with an etching profile having a constant cross-sectional area. In some example embodiments, the MTJ structure 150P may have an etching profile with a slope, wherein the cross-sectional area of the MTJ structure 150P widens from the top to the bottom. In this manner, opposite sidewalls of each MTJ structure may be in some instances parallel, to each other, and in some instances may have a tapered shape with respect to each other.

Referring to FIG. 5C, a passivation layer 170 is formed so as to cover the MTJ structure 150P (e.g., top surfaces and sidewalls of each MTJ structure 150P) and the second interlayer insulating layer 130. The passivation layer 170 may include, for example, a metal oxide formed of metals included in the MTJ structure 150P, which are oxidized to produce the metal oxide. For example, the passivation layer 170 may be formed through an oxidation process or a CVD process.

Oxidation of the first and second magnetization patterns 151P and 155P may be prevented by the passivation layer 170 covering external walls of the MTJ structure 150P.

In one embodiment, a second annealing process is then performed on the MTJ structure 150P. The second annealing process may be performed in a state in which a magnetic field is not formed. The second annealing process may be performed by the batch type annealing device 200 of FIG. 7.

In more detail, the second annealing process may be performed for a second amount of time (e.g., one hour) under a second pressure (e.g., a pressure in a range of 0.1 mTorr or less) and at a second temperature (e.g., temperature in a range of 250° C. to 350° C. In one embodiment, the second amount of time is substantially the same as the first amount of time, though this is not required. In one embodiment, the second pressure is substantially the same as the first pressure, though this is not required. In one embodiment, the second temperature is less than the first temperature. The second annealing process may be performed in a gas atmosphere including at least one of hydrogen, oxygen, and nitrogen. In addition, inert gas may be injected together into the gas atmosphere to control pressure during the second annealing process. Each of the first and second annealing processes may include a heating period where heat sufficient for annealing to occur is applied to the wafers, and a cooling period, where the chamber in which the wafers are contained cools back down to a lower temperature such as room temperature.

A magnetization direction of the MTJ structures 150P formed over the substrate 101 may be made to coincide with a desired direction even in the state in which a magnetic field is not formed. As described above, in order to align a magnetization direction in a desired direction, magnetic field treatment may not be performed simultaneously with an annealing process.

When the second annealing process is completed, the first and second magnetization patterns 151P and 155P may have a cubic structure. For example, when the first and second magnetization patterns 151P and 155P include CoFeB and the tunnel barrier pattern 153P includes MgO, the first and second magnetization patterns 151P and 155P may have a crystal structure oriented in one crystal plane direction of the cubic structure after the second annealing process is completed. This is because, as a result of the second annealing process, the tunnel barrier pattern 153P, which is partially crystallized during the forming operation, has a crystal structure oriented in one crystal plane direction of a body-centered cubic structure, and this affects crystallization of the first and second magnetization patterns 151P and 155P respectively contacting the top and bottom surfaces of the pattern 153P.

Through the first and second annealing processes according to exemplary embodiments, a crystalline orientation of the first and second magnetization patterns 151P and 155P contacting the tunnel barrier pattern 153P may coincide with that of the tunnel barrier pattern 153P. As a result, a Resistance Area (RA) value of the MTJ structure 150P is lowered, and a TMR characteristic may be improved.

Referring to FIG. 5D, after the second annealing process is completed, an isolation insulating layer 180 may be formed on the passivation layer 170 to completely fill a space between the MTJ structures 150P (e.g., also described as MTJ storage elements of an MTJ structure pattern). The isolation insulating layer 180 may include the same material as or similar material to the first interlayer insulating layer 120.

Referring to FIG. 5E, an isolation insulating pattern 180P and a passivation pattern 170P may be formed by performing a planarization process for removing the isolation insulating layer 180 of FIG. 5D and a part of the passivation layer 170 of FIG. 5D, and thereby an upper surface of a capping electrode pattern 160P may be exposed.

The planarization process may be performed, for example, by a CMP process or an etch-back process. The upper surface of the capping electrode pattern 160P and an upper surface of the isolation insulating pattern 180P may be formed to have substantially the same height through the planarization process. The capping electrode pattern 160P may serve as an etch-stop layer.

Referring to FIG. 5F, after the planarization process is completed, an upper capping layer 185 and a third interlayer insulating layer 190 may be sequentially formed so as to cover both the upper surface of the capping electrode pattern 160P and the upper surface of the isolation insulating pattern 180P.

After forming a line-shaped mask pattern on the third interlayer insulating layer 190, the third interlayer insulating layer 190 and the upper capping layer 185 are partially etched to form line-shaped openings through which the capping electrode pattern 160P is exposed.

Next, a conductive material may be formed to fill the openings and a bit line BL may be formed in the openings through a planarization process. A level of an upper surface of the bit line BL may be the same as that of an upper surface of the third interlayer insulating layer 190. The bit line BL may include a metal having low resistivity, for example, Cu.

Ultimately, a variable resistance memory device 100 including variable resistance memory elements may include the substrate 101, the element isolation layer 102 in the substrate 101, the active area ACT defined in the substrate 101 by the element isolation layer 102, the word line WL buried in the substrate 101, the source line SL disposed over the substrate 101, and the MTJ structures 150P which includes a plurality of separated MTJ storage elements.

Furthermore, the variable resistance memory device 100 may further include the first contact plug 123 connecting the source line SL and the active area ACT, the second contact plug 125 connecting the active area ACT and the MTJ structure 150P, a lower electrode pattern 145P and the capping electrode pattern 160P which are arranged so as to be in contact with the MTJ structure 150P, the third contact plug 135 connecting the lower electrode pattern 145P and the second contact plug 125, and the bit line BL connected to the capping electrode pattern 160P. The MTJ structures 150P may each include the first magnetization pattern 151P, the tunnel barrier pattern 153P, and the second magnetization pattern 155P.

A magnetic field treatment process may then be performed on the substrate 101 on which the variable resistance memory device 100 is formed. Magnetization directions of the MTJ structures 150P constituting the variable resistance memory device 100 are aligned through the first and second annealing processes. However, since a plurality of variable resistance memory devices 100 may be arranged on a single substrate 101 (e.g., a plurality of individual integrated circuits forming separate memory chips), a magnetic field treatment process may be performed such that respective magnetization directions of the plurality of variable resistance memory devices 100 are uniformly aligned. The magnetic field treatment process may be performed to reduce scattering between different variable resistance memory devices 100 on a single substrate 101, for example, due to their different locations on the substrate 101.

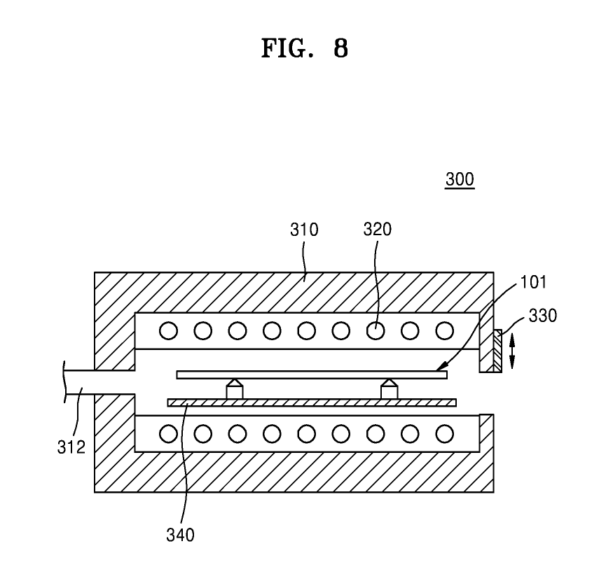

For example, the magnetic field treatment process may be performed at a third temperature (e.g., room temperature). The magnetic field treatment process may be performed in a single-type magnetic field treatment device 300 such as shown in FIG. 8.

In more detail, the magnetic field treatment process may be performed at room temperature for a third amount of time (e.g., one hour) in a magnetic field having a first magnetic flux density (e.g., 1 T to 5 T). The magnetic field treatment process may be performed in an air atmosphere (e.g., an atmosphere including gases normally found in breathable air).

Since a magnetic field of several T is formed during the magnetic field treatment process, magnetization directions of all the variable resistance memory devices 100 on the substrate 101 may be made to coincide with a desired direction. As described above, in order to align a magnetization direction in a desired direction, a magnetic field treatment process may not be performed simultaneously with an annealing process. This final magnetic field treatment process may be described as a refining process, for improving the uniformity of the magnetization direction of the free layer among the separated MTJ storage elements of an individual wafer. For example, the refining process may improve and refine alignment the free layer which has already been aligned through annealing, by applying a magnetic field to the wafer without performing annealing while applying the magnetic field. This may remove small differences in alignment at different locations of the wafer that may have resulted from the previous annealing process or processes. Also, though described above as being performed after completing a plurality of steps to form a variable resistance memory device, the final magnetic field treatment process may be performed after at least one of the steps but before the complete variable resistance memory device has been formed. Additional steps may be performed, after the magnetic field treatment process, such as singulating chips from the wafer, and packaging the chips (e.g., placing them on a package substrate and encapsulating them), to form a semiconductor device.

As used herein, a memory device or semiconductor device may refer, for example, to a device such as a semiconductor chip (e.g., memory chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory elements such MTJ storage elements.

An electronic device, as used herein, may refer to these memory devices or semiconductor devices, but may additionally include products that include these devices, such as a memory module, memory card, hard drive including additional components, or a mobile phone, laptop, tablet, desktop, camera, or other consumer electronic device, etc.

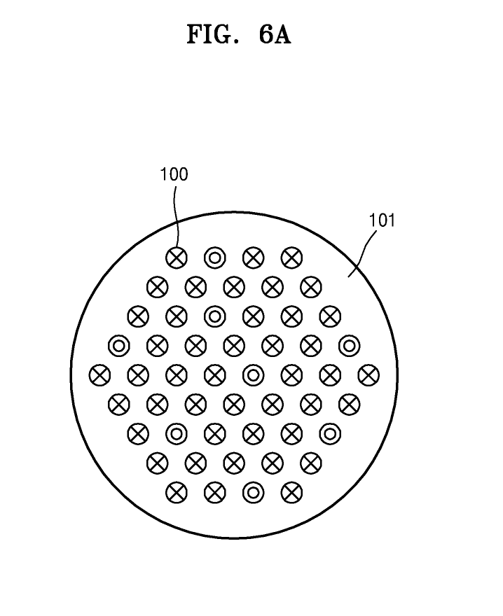

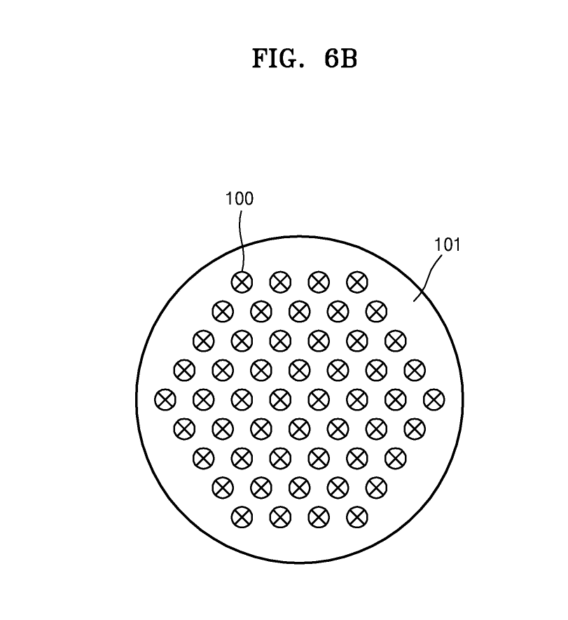

FIGS. 6A and 6B are views for comparing magnetization directions of a variable resistance memory device fabricated by a method of fabricating a memory device according to an example embodiment.

Referring to FIGS. 6A and 6B, respective magnetization directions of all the variable resistance memory devices 100 on the substrate 101 may be aligned in one direction through a magnetic field treatment process.

In FIG. 6A, before a magnetic resistance treatment process is performed on the variable resistance memory devices 100, a magnetization direction O of a variable resistance memory device 100 formed on a portion of the substrate 101 may be different from a magnetization direction X of a variable resistance memory device 100 formed on another portion of the substrate 101. In this case, electrical characteristics of the memory devices are different from each other, and reliability of a product may be lowered.

In FIG. 6B, after a magnetic resistance treatment process is performed on the variable resistance memory devices 100, respective magnetization directions of all the variable resistance memory devices 100 on the substrate 101 may be aligned in one direction (X). Furthermore, productivity and fabrication efficiency of variable resistance memory devices may be improved by performing such a magnetic field treatment process separately from an annealing process.

FIG. 7 is a cross-sectional view of the annealing device 200 for a method of fabricating a memory device according to an example embodiment of the inventive concept.

Referring to FIG. 7, the annealing device 200 may include a reactor 230, a heater coil 220 surrounding the reactor 230, a chamber 210 surrounding the heater coil 220, a gas inlet 212, and a gas outlet 214.

The annealing device 200 may be a first device (e.g., including a first chamber) for performing a first annealing process and/or a second device for performing a second annealing process. The annealing device 200 may be a batch type device. For example, the annealing device 200 may simultaneously process a plurality of substrates 101 in one process. If two separate annealing devices 200 are used, the first one may be described as a first annealing device, for example, including a first annealing chamber, and the second one may be described as a second annealing device, for example, including a second annealing chamber. If only one annealing device 200 is used, it may be referred to as a first annealing device, for example, including a first annealing chamber.

The reactor 230 within the chamber 210 may include an area in which the substrate 101 including the MTJ layer 150 (of FIG. 5A) or the MTJ structure 150P (of FIG. 5C) is disposed. The plurality of substrates 101 may be provided in the reactor 230 at the same time. The plurality of substrates 101 may be arranged parallel to each other in the reactor 230. In some example embodiments, the plurality of substrates 101 may be fixed by a support 240 such that upper surfaces of the plurality of substrates 101 are perpendicular to the ground. In some example embodiments, the plurality of substrates 101 may be fixed by the support 240 such that upper surfaces of the plurality of substrates 101 are arranged horizontally with the ground.

The heater coil 220, generally referred to as a heating element, may supply heat to the MTJ layer 150 or the MTJ structure 150P formed on the plurality of substrates 101. For example, the heater coil 220 may supply heat at a temperature of about 250° C. to 400° C. to the MTJ layer 150 or the MTJ structure 150P. As described above, the first and second magnetization patterns 151P and 155P (of FIG. 5C) may have a crystal structure oriented in one crystal plane direction of a cubic structure, which may be caused by the heat supplied from the heater coil 220.

Process gas may be supplied into the reactor 230 through the gas inlet 212. Process gas may be exhausted outside the reactor 230 through the gas outlet 214.

FIG. 8 is a cross-sectional view of the magnetic field treatment device 300 for a method of fabricating a memory device according to an example embodiment of the inventive concept.

Referring to FIG. 8, the magnetic field treatment device 300 includes a chamber 310 (which may be described as a first, second, or third chamber with respect to chamber(s) of the annealing device(s) 200), a gas line 312 connected to the chamber 310, a superconducting magnet 320 in the chamber 310, and a transfer unit 340 for carrying the substrate 101 in/out of the chamber 310.

The magnetic field treatment device 300 may be a third device (also described as a first or second device in connection with respect to the chamber(s) of the annealing device(s) 200) for performing a magnetic field treatment process. The magnetic field treatment device 300 may be a single-type device. For example, the magnetic field treatment device 300 may process a single substrate 101 in one process. In this manner, the magnetic field treatment device 300, and may include a relatively small superconducting magnet 320, and/or the annealing device 200 may include a relatively small heating element. For example, rather than including a single chamber to perform both annealing and magnetic field treatment on a plurality of wafers, which could require a superconducting magnet and heating element to be comparable in size, separate chambers may be used for annealing and for magnetic field treatment, so a smaller superconducting magnet and/or smaller heating element can be used, while a plurality of wafers can still be heated together in the annealing chamber for greater energy efficiency. Although the magnetic field treatment device 300 is described as a single-type device for processing a single substrate 101, it may be large enough to process a plurality of substrates, but fewer substrates can be processed in the magnetic field treatment chamber. For example, an annealing process may be performed on a plurality of substrates, or first number of substrates, simultaneously, and the magnetic field treatment process may then performed on a set of the plurality of substrates (e.g., a second number of substrates), the set including fewer than all of the plurality of substrates (e.g., including one substrate). Thus, a first chamber may be configured to accommodate the first number of substrates, and the second chamber may be configured to accommodate the second number of substrates.

The chamber 310 forms a space for performing a process on the substrate 101. The gas line 312 may be connected to the chamber 310. Furthermore, a door 330 serving as a path for loading/unloading the substrate 101 may be installed in the chamber 310. The door 330 serves to prevent entrance of outside air into the chamber 310 and to prevent the transfer unit 340 from being separated from the chamber 310 when a magnetic field treatment process proceeds.

The superconducting magnet 320 may supply a magnetic field to the plurality of variable resistance memory devices 100 (of FIG. 5F) formed on the substrate 101. For example, the superconducting magnet 320 may supply a magnetic field having a magnetic flux density of about 1 T to about 5 T to the plurality of variable resistance memory devices 100. Due to the magnetic field supplied from the superconducting magnet 320, respective magnetization directions of the plurality of variable resistance memory devices 100 on the substrate 101 may be aligned in one direction. Furthermore, productivity and fabrication efficiency of variable resistance memory devices may be improved by separating the magnetic field treatment device 300 performing such a magnetic field treatment process from the annealing device 200 (of FIG. 7) performing an annealing process.

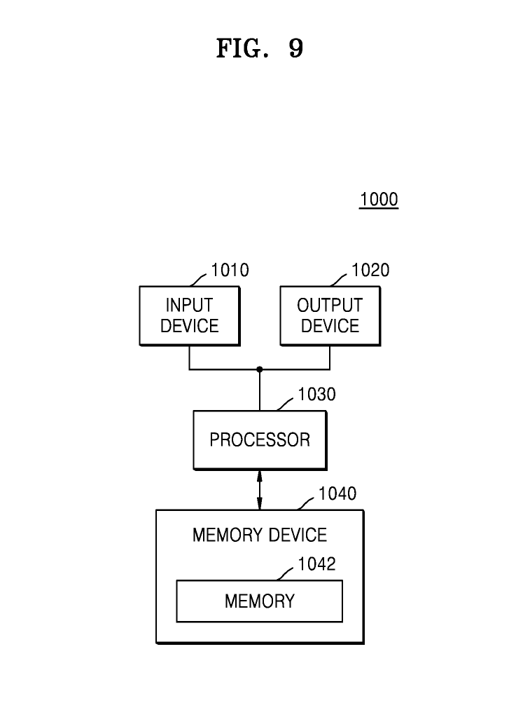

FIG. 9 is a block diagram of an electronic system 1000 including a variable resistance memory device fabricated by a method of fabricating a memory device according to an example embodiment.

Referring to FIG. 9, the electronic system 1000 may include an input device 1010, an output device 1020, a processor 1030, and a memory device 1040. In some example embodiments, the memory device 1040 may include a cell array including non-volatile memory cells and a peripheral circuit for read/write operations. In some example embodiments, the memory device 1040 may include a non-volatile memory device and a memory controller.

A memory 1042 included in the memory device 1040 may include the variable resistance memory device 100 (of FIG. 5F) fabricated by a method of fabricating a memory device according to an example embodiment.

The processor 1030 may be connected to each of the input device 1010, the output device 1020, and the memory device 1040 through an interface, and may control general operations.

While the inventive concept has been particularly shown and described with reference to example embodiments thereof, it will be understood that various changes in form and details may be made therein without departing from the spirit and scope of the following claims.

1. A method of fabricating a memory device, the method comprising:
forming a magnetic tunnel junction (MTJ) layer on a substrate, the MTJ layer including a first magnetization layer, a second magnetization layer, and a tunnel barrier layer between the first magnetization layer and the second magnetization layer;
performing a first annealing process on the MTJ layer;
subsequently forming a plurality of MTJ structures by patterning the MTJ layer;
subsequently performing a second annealing process on the plurality of MTJ structures at a temperature lower than that of the first annealing process;
subsequently performing additional steps to form a variable resistance memory device including the plurality of MTJ structures; and
after performing at least one of the additional steps, performing a magnetic field treatment process on the plurality of MTJ structures.

2. The method of claim 1, wherein:
in the first annealing process, a temperature of the first annealing is higher than a temperature of the second annealing in the second annealing process.

3. The method of claim 2, wherein:
the first annealing process is performed for a first amount of time, and the second annealing process is performed for a second amount of time, wherein the first amount of time is substantially the same as the second amount of time.

4. The method of claim 1, wherein:
the first and second annealing processes are performed in a state in which a magnetic field is not formed.

5. The method of claim 4, wherein:
the magnetic field treatment process is performed in a state in which annealing is not performed.

6. (canceled)

7. The method of claim 5, wherein:
the first annealing process is performed in a first chamber, the magnetic field treatment process is performed in a second chamber different from the first chamber,
the first chamber includes a heating element and does not include a superconducting magnet, and
the second chamber includes a superconducting magnet and does not include a heating element.

8. (canceled)

9. The method of claim 7, wherein:
the first annealing process is performed on a plurality of substrates,
the magnetic field treatment process is performed on a set of the plurality of substrates, the set including fewer than all of the plurality of substrates, and
the set of the plurality of substrates includes one of the plurality of substrates.

10. (canceled)

11. The method of claim 10, wherein,
in the performing of the magnetic field treatment process, the magnetic field treatment process is performed at room temperature.

12. (canceled)

13. The method of claim 1, wherein,
in the forming of the MTJ layer, any one of the first and second magnetization layers is a free layer including a ferromagnetic layer structure, and the other is a fixed layer including a synthetic antiferromagnetic layer structure.

14-15. (canceled)

16. The method of claim 1, wherein
magnetization directions of the plurality of MTJ structures on the substrate are aligned by the performing the first and second annealing processes, and are refined by performing the magnetic field treatment process.

17. A method of fabricating a memory device, the method comprising:
forming a magnetic tunnel junction (MTJ) layer on a substrate, the MTJ layer including a free layer, a fixed layer, and a tunnel barrier layer between the free layer and the fixed layer;
a first device performing a first annealing process on the MTJ layer;
after performing the first annealing process, forming a plurality of MTJ structures by patterning the MTJ layer;
after forming the plurality of MTJ structures, performing a second annealing process on the plurality of MTJ structures at a temperature lower than that of the first annealing process;
after the second annealing process, performing additional steps to form a variable resistance memory device including the plurality of MTJ structures; and
a second device different from the first device performing a magnetic field treatment process on the plurality of MTJ structures, after one or more of the additional steps, to align magnetization directions of the free layer.

18. The method of claim 17, wherein:
the first device includes a heating element and does not include a superconducting magnet, and
the second device includes a superconducting magnet and does not include a heating element.

19. The method of claim 17, wherein:
the first device is of a batch type configured to perform the first annealing process on a plurality of substrates simultaneously, and
the second device is of a single-type configured to perform the magnetic field treatment process on a single substrate.

20. (canceled)

21. The method of claim 17, wherein:
the first and second annealing processes are each performed at 0.1 mTorr or less.

22. The method of claim 17, wherein:
in the performing of the magnetic field treatment process, magnetic field treatment is performed by the second device at room temperature with a magnetic flux density of 1 T to 5 T.

23. The method of claim 17, wherein:
the first device is a first annealing device, and
the second annealing process is performed by a second annealing device different from the first annealing device and different from the second device that performs the magnetic field treatment process.

24. A method of fabricating a memory device, the method comprising:
forming a magnetic tunnel junction (MTJ) layer on a substrate, the MTJ layer including a first magnetization layer, a second magnetization layer, and a tunnel barrier layer between the first magnetization layer and the second magnetization layer;
subsequently forming a plurality of MTJ structures by patterning the MTJ layer;
performing an annealing process on at least one of the MTJ layer prior to forming the plurality of MTJ structures and the MTJ structures after forming the plurality of MTJ structures;
performing additional steps on the MTJ structures to form a variable resistance memory device including the plurality of MTJ structures; and
after performing at least one of the additional steps, performing a magnetic field treatment process on the plurality of MTJ structures, the magnetic field treatment process being performed without simultaneously performing any annealing process.

25. The method of claim 24, wherein:
the annealing process is performed in a first chamber that includes a heating element and does not include a superconducting magnet, and
the magnetic field treatment process is performed in a second chamber that includes a superconducting magnet and does not include a heating element.

26. The method of claim 25, wherein:
the first chamber is configured to accommodate a first number of substrates and to perform annealing on the first number of substrates simultaneously, and
the second chamber is configured to accommodate a second number of substrates and to perform the magnetic field treatment process on the second number of substrates,
wherein the second number of substrates is smaller than the first number of substrates.

27. (canceled)

28. The method of claim 24, wherein the annealing process is a first annealing process performed on the MTJ layer prior to forming the plurality of MTJ structures, and further comprising:
performing a second annealing process on the plurality of MTJ structures subsequent to forming the plurality of MTJ structures, the second annealing process being performed at a lower temperature than the first annealing process.
